(19) United States
(12) Patent Application Publication
(10) Pub. No.: US 2015/0373845 A1
(43) Pub. Date: Dec. 24, 2015

(54) ELECTRONIC COMPONENT MOUNTING STRUCTURE AND METHOD OF MANUFACTURING ELECTRONIC COMPONENT MOUNTING STRUCTURE

(71) Applicant: Panasonic Intellectual Property Management Co., Ltd., Osaka (JP)

(72) Inventors: Yoshiyuki WADA, Osaka (JP); Tadahiko SAKAI, Osaka (JP)

(21) Appl. No.: 14/735,605

(22) Filed: Jun. 10, 2015

(30) Foreign Application Priority Data
Jun. 24, 2014 (JP) 2014-128751
Jun. 24, 2014 (JP) 2014-128752

(51) Int. Cl. H05K 1/11; H05K 3/34

(52) U.S. Cl. CPC H05K 1/11; H05K 3/3494

(57) ABSTRACT

In an electronic component mounting structure, a plurality of bumps formed on an electronic component is joined to a plurality of electrodes formed on a substrate by way of joining portions formed with the bumps and solder. Bonding portions bond the electronic component to the substrate and the bonding portions are formed of thermosetting materials obtained by curing thermosetting resins having a curing temperature which is lower than a melting point of the solder between the electronic component and the substrate. The thermosetting materials come in contact with a nearest-neighboring joining portion in the bonding portions.

### CROSS REFERENCE TO RELATED APPLICATIONS

This application is based upon and claims the benefit of priority of Japanese Patent Application No. 2014-128751 and No. 2014-128752, both filed on Jun. 24, 2014, the contents of which are incorporated herein by reference in its entirety.

### BACKGROUND OF THE INVENTION

1. Field of the Invention

The present invention relates to an electronic component mounting structure manufactured by mounting an electronic component such as Ball Grid Array (BGA) package on which a plurality of bumps is formed on a substrate, and a method of manufacturing the electronic component mounting structure.

2. Description of the Related Art

A method of mounting an electronic component such as a semiconductor device, a method of connecting the electronic component on a substrate by joining a plurality of bumps formed at a main surface of the electronic component to electrodes formed on the substrate through soldering has been widely used (for example, see JP-A-10-112478). In the related art described in JP-A-10-112478, in a configuration in which a BGA type semiconductor device is mounted on a substrate, four corner positions of outer edges of the BGA type semiconductor device are joined to the substrate by using adhesive. Thus, an effect of correcting warp deformation of the BGA type semiconductor device which arises in a heating process during reflow soldering is obtained.

Patent Document 1: JP-A-10-112478

### SUMMARY OF THE INVENTION

Incidentally, in the manufacturing field of electronic devices, as portable devices represented by smart phones become small and thin, there is an increasing demand for space-saving and size reduction of an electronic component mounted on these devices. Particularly, among these demands, it is more important to manufacture the electronic component to be thin than in the related art. For this reason, as the electronic component and the substrate become thin and have low stiffness, warp deformation in an upward and downward direction (thickness direction) or positional deviation easily occurs in a heating process when the electronic component is joined to the substrate through soldering. As a result, defects arising from the warp deformation, such as a solder opening phenomenon in which the bumps of the electronic component are separated from the electrodes of the substrate without normally coming in contact with the electrodes or a bridge phenomenon in which the neighbor electrodes are connected each other through the solder by excessively pushing the bumps against the substrate, frequently occur. However, as in the related art described above, it is difficult to effectively prevent the warp deformation from occurring in the electronic component which is extremely thin and is easily bent.

Accordingly, a non-limited object of the present invention is to provide an electronic component mounting structure and a method of manufacturing an electronic component mounting structure which are capable of reducing defects arising from warp deformation even when an electronic component and a substrate which are thin and have low stiffness are used.

A first aspect of the present invention provides an electronic component mounting structure in which a plurality of bumps formed on an electronic component is joined to a plurality of electrodes formed on a substrate by way of joining portions formed with the bumps and solder, the structure including: bonding portions that bond the electronic component to the substrate in plurality of preset positions, wherein the bonding portions are formed by thermosetting materials obtained by curing thermosetting resins having a curing temperature which is lower than a melting point of the solder between the electronic component and the substrate, wherein the bonding portions include a bump bonding portion provided in a bump-forming region where the bumps are formed, and the thermosetting materials come in contact with a nearest-neighboring joining portion of the joining portions at least in the bump bonding portion.

A second aspect of the present invention provides a method of manufacturing an electronic component mounting structure in which a plurality of bumps formed on an electronic component is joined to a plurality of electrodes formed on a substrate by way of joining portions formed with the bumps and solder, the method including: supplying solder pastes to the electrodes; supplying thermosetting resins having a curing temperature which is lower than a melting point of the solder in preset resin supplying positions in order to bond the electronic component to the substrate in a plurality of positions on a component mounting surface of the substrate; mounting the electronic component on the substrate by disposing the plurality of bumps on the solder pastes supplied to the corresponding electrodes while bringing the electronic component into contact with the thermosetting resins; forming bonding portions that bond the electronic component to the substrate with thermosetting materials obtained by heating the substrate on which the electronic component is mounted at a temperature lower than the melting point of the solder and thermally curing the thermosetting resins between the electronic component and the substrate; joining the bumps to the electrodes through soldering by further heating the substrate and melting the solder; and solidifying the melted solder by cooling the substrate, wherein the resin supplying positions include a bump-region resin supplying position provided in a bump-forming region where the bumps are formed, and the resins are supplied such that the thermosetting materials come in contact with a nearest-neighboring joining portion at least in the bump-region resin supplying position at a timing at which cooling the substrate is completed.

A third aspect of the present invention provides an electronic component mounting structure in which a plurality of bumps formed on an electronic component is joined to a plurality of electrodes formed on a substrate by way of joining portions formed with the bumps and solder, the structure including: bonding portions that bond the electronic component to the substrate, wherein the bonding portions are formed of thermosetting materials obtained by curing thermosetting resins having a curing temperature which is lower than a melting point of the solder between the electronic component and the substrate, wherein the thermosetting materials come in contact with a nearest-neighboring joining portion in the bonding portions.

A fourth aspect of the present invention provides a method of manufacturing an electronic component mounting structure in which a plurality of bumps formed on an electronic component is joined to a plurality of electrodes formed on a substrate by way of joining portions formed with the bumps and solder, the method including: supplying solder pastes to the electrodes; supplying thermosetting resins having a curing temperature which is lower than a melting point of the solder on a component mounting surface of the substrate; mounting the electronic component on the substrate by disposing the plurality of bumps on the solder pastes supplied to the corresponding electrodes while bringing the electronic component into contact with the thermosetting resins; forming bonding portions that bond the electronic component to the substrate with thermosetting materials obtained by heating the substrate on which the electronic component is mounted at a temperature lower than the melting point of the solder and thermally curing the thermosetting resins between the electronic component and the substrate; joining the bumps to the electrodes through soldering by further heating the substrate and melting the solder; and solidifying the melted solder by cooling the substrate, wherein the resins are supplied such that the thermosetting materials come in contact with a nearest-neighboring joining portion at a timing at which cooling the substrate is completed.

According to any of the aspects of the present invention, it is possible to reduce defects arising from warp deformation even when an electronic component and a substrate which are thin and have low stiffness are used.

### BRIEF DESCRIPTION OF THE DRAWINGS

In the accompanying drawings:

FIGS. 1A and 1B are explanatory diagrams showing the configuration of an electronic component mounting structure according to an embodiment of the present invention;

FIGS. 2A to 2D are explanatory process diagrams showing a method of manufacturing the electronic component mounting structure according to the embodiment of the present invention;

FIGS. 3A to 3C are explanatory process diagrams showing the method of manufacturing the electronic component mounting structure according to the embodiment of the present invention;

FIG. 4 is a graph showing a heating profile of a heating process in the method of manufacturing the electronic component mounting structure according to the embodiment of the present invention;

FIGS. 5A and 5B are cross-sectional views of the electronic component mounting structure according to an embodiment of the present invention;

FIGS. 6A to 6C are plan views showing an arrangement pattern of bonding portions in the electronic component mounting structure according to the embodiment of the present invention;

FIGS. 7A and 7B are plan views showing an arrangement pattern of the bonding portions in the electronic component mounting structure according to the embodiment of the present invention;

FIGS. 8A and 8B are cross-sectional views of the electronic component mounting structure according to the embodiment of the present invention; and

FIGS. 9A to 9D are explanatory process diagrams showing the method of manufacturing the electronic component mounting structure according to another embodiment of the present invention.

### DETAILED DESCRIPTION OF THE EXEMPLARY EMBODIMENTS

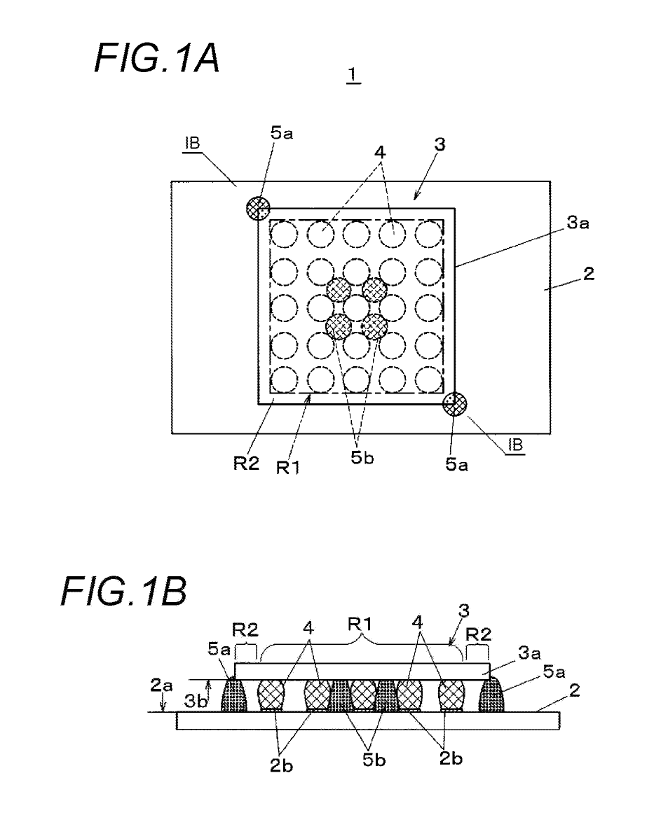

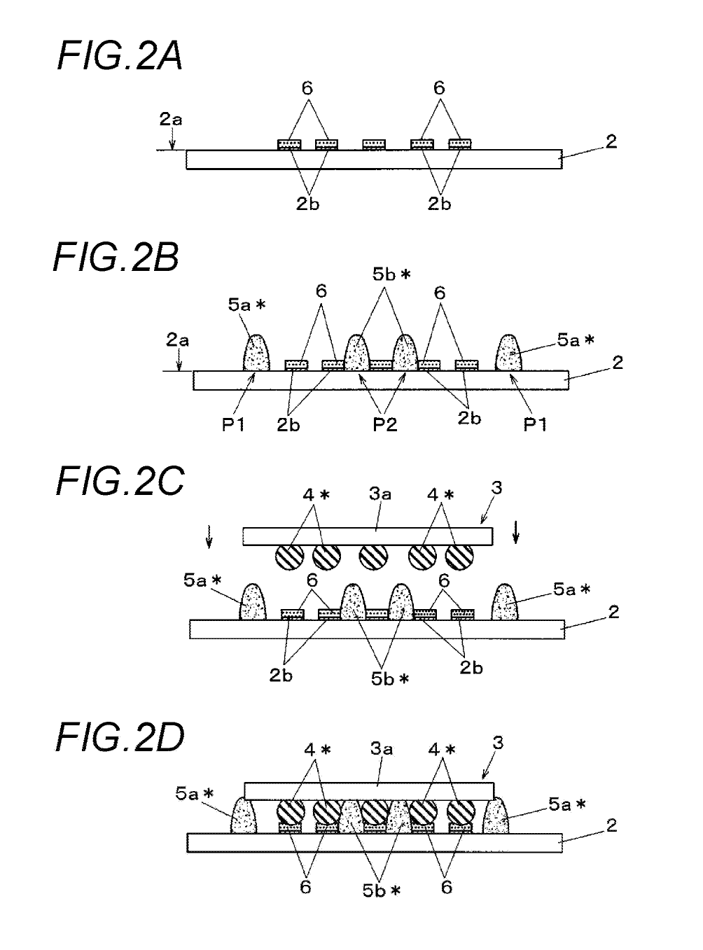

Hereinafter, embodiments of the present invention will be described with reference to the drawings. The configuration of an electronic component mounting structure 1 will first be described with reference to FIGS. 1A and 1B. FIG. 1B shows a cross section taken along line IB-IB in FIG. 1A, that is, a cross section of a planar shape of an electronic component 3 in a diagonal direction. As shown in FIG. 1B, a plurality of electrodes 2b is formed on a component mounting surface 2a of a substrate 2. The electronic component 3 has a configuration in which bumps 4* (see FIG. 2D) are formed on a lower surface 3b of a rectangular body part 3a so as to correspond to the arrangement of the electrodes 2b in the substrate 2.

In the electronic component mounting structure 1 in which the electronic component 3 has been mounted on the substrate 2, bump joining portions 4 formed by joining the bumps 4* to the electrodes 2b through soldering are formed. That is, the electronic component mounting structure 1 is manufactured by joining the plurality of bumps 4* formed on the electronic component 3 to the plurality of electrodes 2b formed on the substrate 2 by the joining portions (bump joining portions 4) formed by soldering the bumps 4*. In the illustrated example, the electronic component mounting structure 1 is a thin-type package used for a portable device, and both the substrate 2 and the electronic component 3 that are used are thin and have low stiffness.

In the electronic component mounting structure 1, outer edge bonding portions 5a and bump bonding portions 5b which are bonding portions for bonding the substrate 2 to the electronic component 3 are formed in a plurality of positions between the component mounting surface 2a of the substrate 2 and the lower surface 3b of the electronic component 3. Both the outer edge bonding portions 5a and the bump bonding portions 5b are formed of a thermosetting material obtained by curing a thermosetting resin, which has a curing temperature lower than the melting point of solder, between the electronic component 3 and the substrate 2. As a thermosetting resin, an epoxy resin, a phenol resin, and a melamine resin are used. The curing temperature of the thermosetting resin in the present embodiment is calculated as a peak temperature of a curve indicating the relationship between the temperature and heat flow obtained by differential scanning calorimetry (DSC).

Here, the body part 3a is divided into a bump-forming region R1 which is a region where the bumps 4* are formed and an outer-edge region R2 which is a region outside the bump-forming region R1. The forming positions of the outer edge bonding portions 5a correspond to the outer-edge region R2, and the forming positions of the bump bonding portions 5b correspond to the bump-forming region R1. That is, the outer edge bonding portions 5a are formed in two facing diagonal positions in the body part 3a, and the bump bonding portions 5b are set in a plurality of positions (here, four places) surrounding the bumps 4* positioned in the center of the bump-forming region R1.

In the electronic component mounting structure 1 having the above configuration, the thermosetting material of the thermosetting resin comes in contact with the surrounding nearest-neighboring bump joining portions 4 in the bump bonding portions 5b, which are formed in the bump-forming region R1, of the outer edge bonding portions 5a and the bump bonding portions 5b. That is, in the present embodiment, among the bonding portions, the thermosetting material of the thermosetting resin comes in contact with the nearest-neighboring bump joining portions 4 in at least the bump bonding portions 5b set in the bump-forming region R1.

Here, a guanidine-based activator including diphenylguanidine is contained in the thermosetting resin of the bump bonding portions 5b. Through the operation of this activator, a bonding effect due to the curing of the thermosetting resin in the heating process after the component is mounted is prompted, and it is possible to obtain an effect of further improving bonding properties by bringing the activator in the bump bonding portions 5b into contact with the metal surfaces of the surrounding bump joining portions 4.

Next, an electronic-component-mounting-structure manufacturing method of manufacturing the electronic component mounting structure 1 will be described with reference to FIGS. 2A to 4. As shown in FIG. 2A, solder in a paste form (solder pastes 6) such as cream solder is supplied through screen printing to the electrodes 2b (solder paste supplying process).

Subsequently, as shown in FIG. 2B, thermosetting resins 5a* and 5b* are supplied onto the component mounting surface 2a of the substrate 2 (resin supplying process). Here, the curing temperature of the thermosetting resins 5a* and 5b* is set to be lower than the melting point of the solder included in the solder pastes 6 and the solder in the bumps 4*, and in the subsequent heating process, the thermosetting resins 5a* and 5b* are previously cured before the solder in the solder pastes 6 and the bumps 4* is melted.

In the present embodiment, the thermosetting resins 5a* and the thermosetting resins 5b* are respectively supplied to outer-edge-region resin supplying positions P1 and bump-region resin supplying positions P2 by using an application tool such as dispensers so as to correspond to the positions of the outer edge bonding portions 5a and the bump bonding portions 5b shown in FIGS. 1A and 1B. When the resins are supplied in the resin supplying process, the application positions and application amounts are set in the electronic component mounting structure 1, that is, at the timing at which a cooling process of the solder joining is completed such that the thermosetting materials obtained by curing these resins come in contact with the nearest-neighboring bump joining portions 4.

Here, although it has been described that all of the thermosetting resins 5a* and 5b* have the same composition, the compositions of the thermosetting resins 5a* applied to the outer-edge-region resin supplying positions P1 and the thermosetting resins 5b* applied to the bump-region resin supplying positions P2 may be different depending on the bonding characteristics of the outer edge bonding portions 5a and the bump bonding portions 5b. For example, the activator described above may be added only to the thermosetting resins 5b* applied to the bump-region resin supplying positions P2.

Subsequently, the electronic component 3 is mounted on the substrate 2 to which the resins have been supplied (mounting process). Here, as shown in FIG. 2C, the electronic component 3 is lowered toward the substrate 2 while the respective bumps 4* are aligned with the electrodes 2b. Subsequently, as shown in FIG. 2D, the electronic component 3 is mounted on the substrate 2 by disposing the plurality of bumps 4* on the solder pastes 6 supplied to the corresponding electrodes 2b while the body part 3a of the electronic component 3 comes in contact with the thermosetting resins 5a* and 5b*.

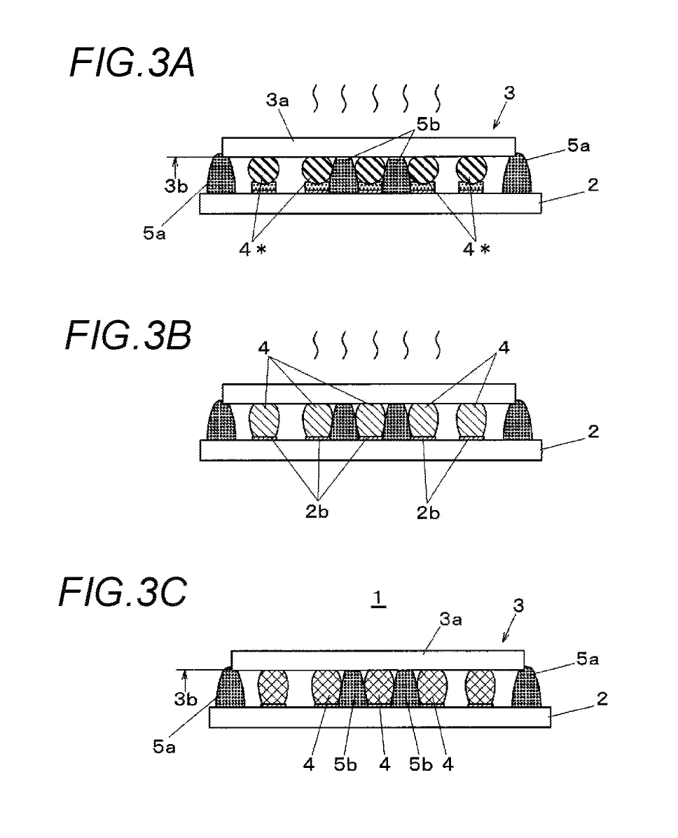

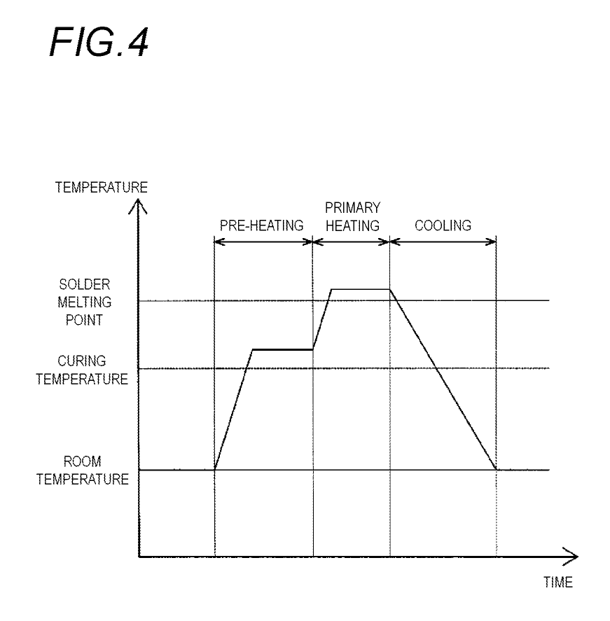

Thereafter, the substrate 2 on which the mounting process has been performed is sent to a reflow apparatus, and is heated according to a heating profile shown in FIG. 4. In the reflow apparatus, the substrate is first heated up to a temperature, which is higher than the curing temperature of the thermosetting resins 5a* and 5b* and is lower than the melting point of the solder, through pre-heating. Thus, as shown in FIG. 3A, the thermosetting resins 5a* and 5b* are thermally cured, and the outer edge bonding portions 5a and the bump bonding portions 5b, which are made from these thermosetting materials, are formed.

That is, the outer edge bonding portions 5a and the bump bonding portions 5b for bonding the electronic component 3 to the substrate 2 are formed by the thermosetting materials obtained by heating the substrate 2 on which the mounting process has been performed at a temperature which is lower than the melting point of the solder and thermally curing the thermosetting resins 5a* and 5b* between the electronic component 3 and the substrate 2 (thermal curing process). In general, in order to completely cure the thermosetting resins, it is necessary to heat the thermosetting resins at a temperature which is higher than the curing temperature for a predetermined time. However, it is not necessary to completely cure the thermosetting resins in the thermal curing process of the present embodiment, and the thermosetting resins may be in a semi-cured state obtained when the heating time is shortened.

Subsequently, a primary heating process is performed. That is, the melted bump joining portions 4 are formed by raising the temperature up to the temperature higher than the melting temperature of the solder by further heating the substrate 2 and melting solder compositions contained in the bumps 4* and the solder pastes 6 as shown in FIG. 3B (melting process). Subsequently, the melted bump joining portions 4 are solidified by taking the substrate 2 out of a heating zone and cooling the substrate 2 (cooling process). Thus, as shown in FIG. 3C, the bump joining portions 4 for joining the bumps 4* formed at the electronic component 3 to the electrodes 2b of the substrate 2 through soldering are formed. In such a state, the thermosetting materials obtained by thermally curing the thermosetting resins 5b* come in contact with the nearest-neighboring bump joining portions 4 while surrounding the nearest-neighboring bump joining portions. Thus, the thermosetting resins 5b* are fixed to the bump joining portions 4 as well as the lower surface 3b of the electronic component 3, and thus, the fixation maintaining force for bonding the electronic component 3 to the substrate 2 is improved.

The operation and function of the outer edge bonding portions 5a and the bump bonding portions 5b in the aforementioned thermal curing process will be described. As described above, both the substrate 2 and the electronic component 3 used in the electronic component mounting structure 1 are thin and have low stiffness, and also have characteristics that bending is easily caused therein due to thermal deformation. For this reason, in the heating process after the component is mounted, warp deformation occurs in the substrate 2 and the body part 3a of the electronic component 3, and defects arising from this warp deformation frequently occur. Even when the substrate 2 and the electronic component 3 which are thin and have low stiffness are used, the thermosetting resins 5a* and 5b* are thermally cured through the pre-heating before the solder joining is performed on the bumps 4* in the primary heating process in the present embodiment. Thus, it is possible to effectively prevent the warp deformation due to the effect of maintaining the fixation of the body part 3a to the substrate 2 through the outer edge bonding portions 5a and the bump bonding portions 5b.

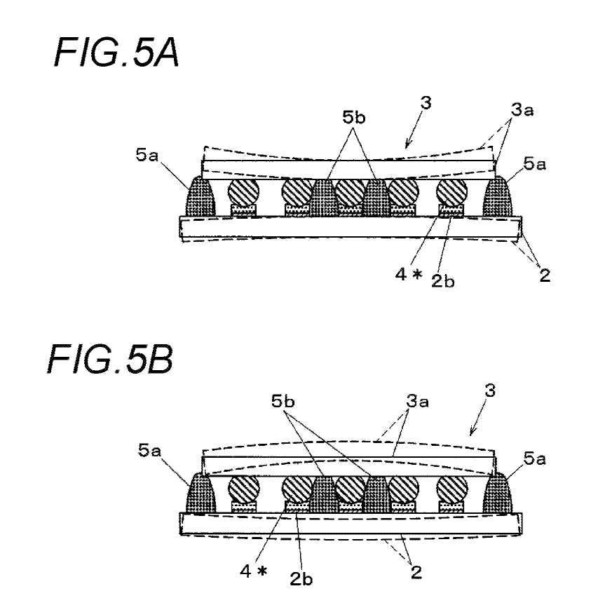

FIGS. 5A and 5B show two examples in which such warp deformation occurs most markedly. That is, FIG. 5A shows an example in which the body part 3a has warp-upward characteristics and the substrate 2 has warp-downward characteristics and a joining failure arising from the warp deformation easily occurs in both ends of the electronic component mounting structure 1. Even in such a case, the fixation of the substrate 2 to the body part 3a is maintained by the bump bonding portions 5b around the center, and the fixation thereof is maintained by the outer edge bonding portions 5a in both ends. Thus, defects which arise from the warp deformation, such as a solder opening phenomenon in which a gap is formed between the bumps 4* and the electrodes 2b in both ends and a bridge phenomenon in which the neighboring electrodes 2b are connected through the solder by excessively pushing the bumps 4* against the substrate around the center, do not occur.

FIG. 5B shows an example in which the body part 3a has warp-downward characteristics and the substrate 2 has warp-upward characteristics and a joining failure arising from the warp deformation easily occurs in the central portion of the electronic component mounting structure 1. Even in such a case, similarly to the above example, since the fixation of the substrate 2 to the body part 3a is maintained by the outer edge bonding portions 5a and the bump bonding portions 5b, the defects arising from warp deformation do not occur.

In the above examples, as an arrangement example of the outer edge bonding portions 5a and the bump bonding portions 5b, it has been described that the outer edge bonding portions 5a are set to the two facing diagonal positions in the body part 3a and the bump bonding portions 5b are set to the plurality of positions surrounding the bumps 4* positioned in the center in the bump-forming region R1 as shown in FIGS. 1A and 1B. However, the present invention is not limited to such a bonding portion arrangement, and multiple variations, to be illustrated below, are possible. Such variations are individually determined in consideration of the warp deformation characteristics, planar shapes and bump arrangement of the electronic component 3 and the substrate 2 which are targets.

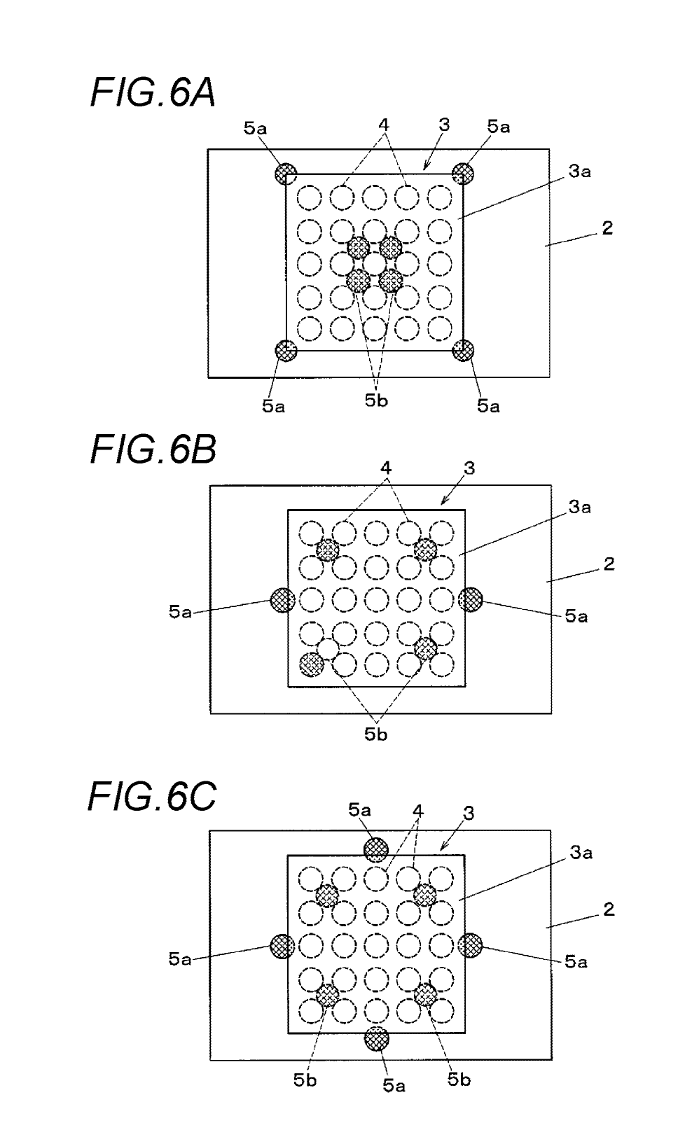

For example, in the example shown in FIG. 6A, the outer edge bonding portions 5a are arranged in all of the diagonal positions of the rectangular body part 3a in addition to the arrangement pattern shown in FIG. 1A. In the example shown in FIG. 6B, the plurality of bump bonding portions 5b is arranged in the bump-forming region R1, and the outer edge bonding portions 5a are arranged at the central points of two facing sides of the body part 3a. FIG. 6C shows that the outer edge bonding portions 5a are arranged at the central points of all four sides of the body part 3a in addition to the arrangement pattern of FIG. 6B.

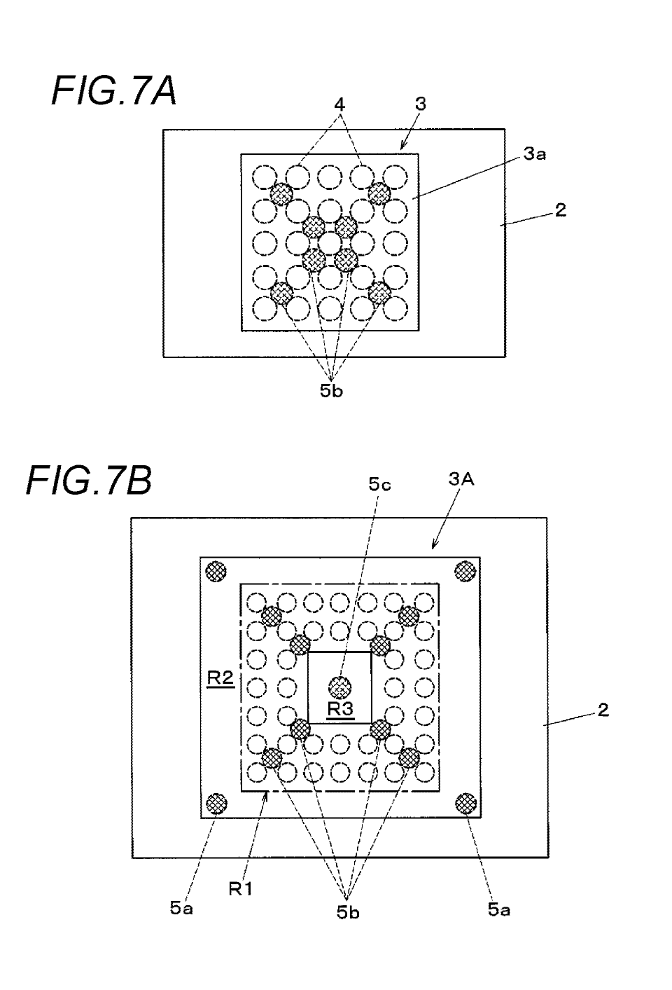

FIG. 7A shows an arrangement pattern in which only the plurality of bump bonding portions 5b is arranged within the bump-forming region R1 without setting the outer edge bonding portions 5a. FIG. 7B shows an example in which an electronic component 3A having a large planar size is used and a bump-free region R3 where the bumps are not present in the center of the bump-forming region R1 is present. Here, an example in which additional bonding portions 5c are additionally arranged in the bump-free region R3 in addition to the outer edge bonding portions 5a arranged in the outer-edge region R2 and the bump bonding portions 5b arranged in the bump-forming region R1 is illustrated.

Although it has been described in the above embodiment that the bump joining portions 4 are formed by joining the bumps 4* formed through the soldering to the electrodes 2b through the solder pastes 6, the material of the bumps 4* is not limited to the solder, and may be metal such as gold (Au) having a higher melting point than that of the solder or may be solder metal having a higher melting point than that of the solder in the solder paste 6. When the bump joining portions 4 are joined through the soldering, the solder included in the solder pastes 6 that have been previously supplied to the electrodes 2b contribute to the joining thereof. However, when the material of the bumps 4* is solder, the solder in the bumps 4* contributes to the joining thereof.

It has been described in the above embodiment that the bump bonding portions 5b are arranged in the bump-forming region R1 and the outer edge bonding portions 5a are arranged in the diagonal positions of the outer-edge region R2, as the bonding portions for bonding the electronic component 3 to the substrate 2. However, the arrangement positions of the bonding portions having such functions are not limited those in the above example, and may be arbitrarily set depending on the shapes and sizes of the electronic component 3 and the substrate 2 which are targets.

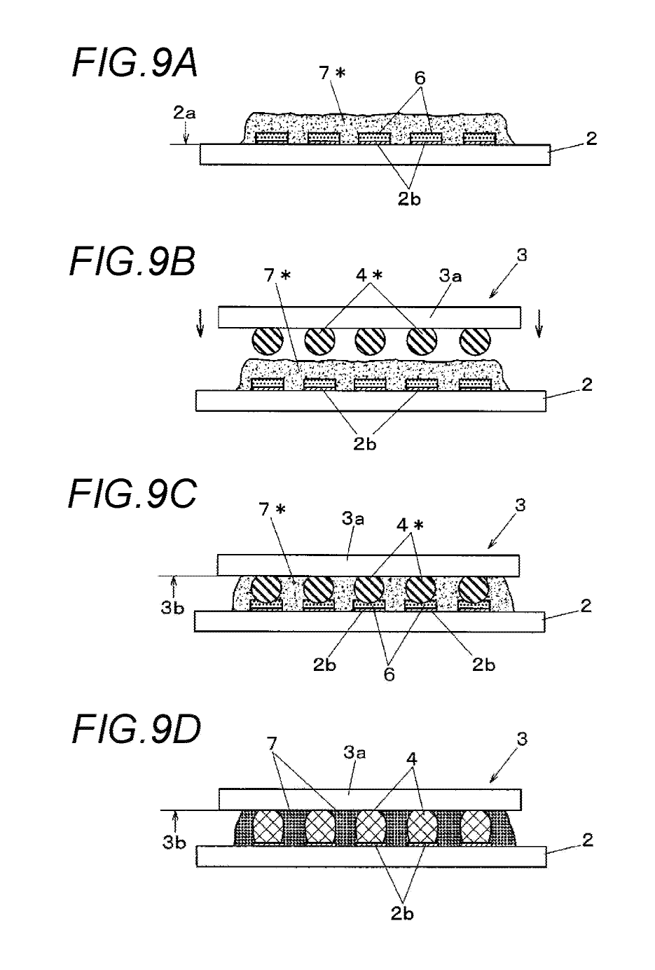

FIGS. 9A to 9D show an arrangement example of the bonding portions. In the illustrated arrangement example, the entire surface of the component mounting surface 2a corresponding to the bump-forming region R1 shown in FIG. 1B is a bonding portion 7 for bonding the substrate 2 to the electronic component 3. That is, as shown in FIG. 9A, the same thermosetting resin 7* as the thermosetting resins 5b* is applied to the substrate 2 on which the solder paste supplying process shown in FIG. 2A has been performed so as to surround the solder pastes 6. Subsequently, the electronic component 3 is mounted on the substrate 2 to which the resin has been supplied. Here, as shown in FIG. 9B, the electronic component 3 is lowered toward the substrate 2 while the respective bumps 4* are aligned with the electrodes 2b. Subsequently, as shown in FIG. 9C, the body part 3a of the electronic component 3 comes in contact with the thermosetting resin 7*. In addition, the electronic component is mounted on the substrate 2 by lowering the plurality of bumps 4* while pushing the thermosetting resin 7* and disposing the bumps on the solder pastes 6 supplied to the corresponding electrodes 2b.

Thereafter, the substrate 2 on which the electronic component 3 has been mounted is sent through the heating process, and is heated according to the heating profile shown in FIG. 4. Here, the fixation of the electronic component 3 to the substrate 2 over almost the entire surface thereof is maintained by thermally curing the thermosetting resin 7* through pre-heating and forming a bonding portion 7 with the thermosetting material. Subsequently, the primary heating is performed, and the solder in the bumps 4* and the solder pastes 6 is melted and is joined to the electrodes 2b through the soldering, so that the bump joining portions 4 are formed. In the illustrated example, a strong bonding effect is obtained through a simple process of applying the thermosetting resin 7* to the entire surface.

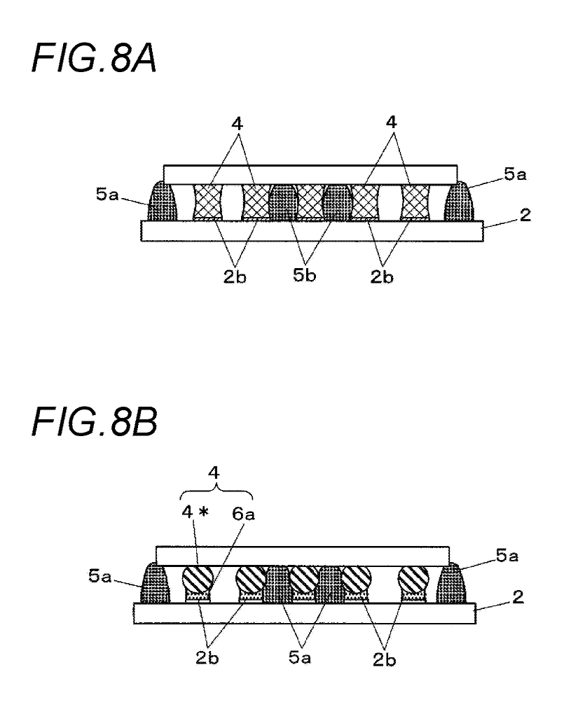

FIGS. 8A and 8B show an example of the shape of the bump joining portions 4 in the electronic component mounting structure 1 of the present embodiment. That is, when the melting point of the solder in the bumps 4* approximates the melting point of the solder included in the solder paste 6, the bump joining portions 4 have a barrel shape shown in FIG. 1B or a bobbin shape shown in FIG. 8A. Meanwhile, when the bumps 4* are metal such as Au having the temperature higher than the melting point of the solder or solder metal having a higher temperature than the melting point of the solder paste 6, the bump joining portions 4 have a skirt shape such that solder 6a included in the solder pastes 6 spreads so as to be buried between the bumps 4* and the electrodes 2b, as shown in FIG. 8B.

As described above, in the present embodiment, when the electronic component mounting structure is manufactured by joining the plurality of bumps formed on the electronic component to the plurality of electrodes formed on the substrate by way of the joining portions formed with the bumps and solder, the bonding portions for bonding the electronic component to the substrate are formed in the plurality of preset positions by using the thermosetting materials obtained by thermally curing the thermosetting resins having a curing temperature which is lower than the melting point of the solder between the electronic component and the substrate, and the thermosetting materials come in contact with the nearest-neighboring joining portions in the bonding portions. Thus, it is possible to stably maintain the bonding of the electronic component to the substrate by using the bonding portions, and even when the electronic component and the substrate which are thin and have low stiffness are used, it is possible to reduce the defects arising from the warp deformation.

As described above, in the present embodiment, when the electronic component mounting structure is manufactured by joining the plurality of bumps formed on the electronic component to the plurality of electrodes formed on the substrate by way of the joining portions formed with the bumps and solder, the bonding portions for bonding the electronic component to the substrate are formed of the thermosetting materials obtained by thermally curing the thermosetting resins having a curing temperature which is lower than the melting point of the solder between the electronic component and the substrate, and the thermosetting materials come in contact with the nearest-neighboring joining portions in the bonding portions. Accordingly, it is possible to stably maintain the bonding of the electronic component to the substrate through the bonding portions, and even when the electronic component and the substrate which are thin and have low stiffness are used, it is possible to reduce the defects arising from the warp deformation.

The electronic component mounting structure and the method of manufacturing the electronic component mounting structure according to the embodiments of the present invention may exhibit an advantage capable of reducing the defects arising from the warp deformation even when the electronic component and the substrate which are thin and have low stiffness are used, and are useful in the manufacturing field of a semiconductor device on which semiconductor elements are mounted on a thin substrate.

What is claimed is:

1. An electronic component mounting structure in which a plurality of bumps formed on an electronic component is joined to a plurality of electrodes formed on a substrate by way of joining portions formed with the bumps and solder, the structure comprising:
bonding portions that bond the electronic component to the substrate in plurality of preset positions, wherein the bonding portions are formed by thermosetting materials obtained by curing thermosetting resins having a curing temperature which is lower than a melting point of the solder between the electronic component and the substrate, wherein
the bonding portions include a bump bonding portion provided in a bump-forming region where the bumps are formed, and the thermosetting materials come in contact with a nearest-neighboring joining portion of the joining portions at least in the bump bonding portion.

2. The electronic component mounting structure according to claim 1, wherein the bonding portions further include an outer edge bonding portion provided in an outer-edge region outside the bump-forming region.

3. The electronic component mounting structure according to claim 1, wherein the thermosetting resin includes an activator.

4. A method of manufacturing an electronic component mounting structure in which a plurality of bumps formed on an electronic component is joined to a plurality of electrodes formed on a substrate by way of joining portions formed with the bumps and solder, the method comprising:
supplying solder pastes to the electrodes;
supplying thermosetting resins having a curing temperature which is lower than a melting point of the solder in preset resin supplying positions in order to bond the electronic component to the substrate in a plurality of positions on a component mounting surface of the substrate;
mounting the electronic component on the substrate by disposing the plurality of bumps on the solder pastes supplied to the corresponding electrodes while bringing the electronic component into contact with the thermosetting resins;
forming bonding portions that bond the electronic component to the substrate with thermosetting materials obtained by heating the substrate on which the electronic component is mounted at a temperature lower than the melting point of the solder and thermally curing the thermosetting resins between the electronic component and the substrate;
joining the bumps to the electrodes through soldering by further heating the substrate and melting the solder; and
solidifying the melted solder by cooling the substrate, wherein
the resin supplying positions include a bump-region resin supplying position provided in a bump-forming region where the bumps are formed, and the resins are supplied such that the thermosetting materials come in contact with a nearest-neighboring joining portion at least in the bump-region resin supplying position at a timing at which cooling the substrate is completed.

5. The method according to claim 4, wherein the resin supplying positions further include an outer-edge-region resin supplying position provided in an outer-edge region outside the bump-forming region.

6. The method according to claim 4, wherein the thermosetting resin includes an activator.

7. An electronic component mounting structure in which a plurality of bumps formed on an electronic component is joined to a plurality of electrodes formed on a substrate by way of joining portions formed with the bumps and solder, the structure comprising:
bonding portions that bond the electronic component to the substrate, wherein the bonding portions are formed of thermosetting materials obtained by curing thermosetting resins having a curing temperature which is lower than a melting point of the solder between the electronic component and the substrate, wherein
the thermosetting materials come in contact with a nearest-neighboring joining portion in the bonding portions.

8. The electronic component mounting structure according to claim 7, wherein the thermosetting resin includes an activator.

9. A method of manufacturing an electronic component mounting structure in which a plurality of bumps formed on an electronic component is joined to a plurality of electrodes formed on a substrate by way of joining portions formed with the bumps and solder, the method comprising:
supplying solder pastes to the electrodes;
supplying thermosetting resins having a curing temperature which is lower than a melting point of the solder on a component mounting surface of the substrate;
mounting the electronic component on the substrate by disposing the plurality of bumps on the solder pastes supplied to the corresponding electrodes while bringing the electronic component into contact with the thermosetting resins;
forming bonding portions that bond the electronic component to the substrate with thermosetting materials obtained by heating the substrate on which the electronic component is mounted at a temperature lower than the melting point of the solder and thermally curing the thermosetting resins between the electronic component and the substrate;
joining the bumps to the electrodes through soldering by further heating the substrate and melting the solder; and
solidifying the melted solder by cooling the substrate, wherein
the resins are supplied such that the thermosetting materials come in contact with a nearest-neighboring joining portion at a timing at which cooling the substrate is completed.

10. The method according to claim 9, wherein the thermosetting resin includes an activator.
